(19) United States
(12) Patent Application Publication
(10) Pub. No.: US 2011/0303635 A1
(43) Pub. Date: Dec. 15, 2011

(54) DRY ETCHING APPARATUS AND METHOD OF DRY ETCHING

(76) Inventor: Shuji TAKAHASHI, Kanagawa-ken (JP)

(21) Appl. No.: 13/157,470

(22) Filed: Jun. 10, 2011

(30) Foreign Application Priority Data
Jun. 11, 2010 (JP) 2010-134016

(51) Int. Cl. H01L 41/24; C23F 1/08

(52) U.S. Cl. 216/13; 156/345.28; 216/61

(57) ABSTRACT

A dry etching apparatus includes: a vacuum chamber which includes therein a stage on which a member to be etched is mounted; a process gas supply device which supplies a process gas into the vacuum chamber; a plasma generating device which includes an electrode for generating a plasma in the vacuum chamber; a plasma generating power source which supplies high-frequency power for plasma generation to the electrode of the plasma generating device; a bias power source which is a single bias power source for controlling a self-bias potential of the stage and from which output frequency is variable; a matching box which is a single matching box connected electrically between the stage and the bias power source and which matches impedances between a load of the bias power source and the bias power source; a frequency setting device which sets an output frequency of the bias power source; and a control device which controls an impedance of the matching box according to the set output frequency of the bias power source.

### BACKGROUND OF THE INVENTION

1. Field of the Invention

The present invention relates to a dry etching apparatus and a method of dry etching and, in particular, to technique for carrying out etching at an optimal frequency on an object to be etched.

2. Description of the Related Art

Generally, when dry etching is carried out in order to process material which is difficult to be etched such as a ferroelectric used in a ferroelectric memory (FeRAM) or a piezoelectric element and precious metals used in the electrodes, a plasma is generated using a mixed gas including a halogen gas or an inert gas (for example, Ar gas) and a high frequency wave is applied to a stage on which a member to be etched is mounted, and then ions in the plasma are brought in.

In particular, when a piezoelectric element is processed, etching is carried out on a substrate on which a piezoelectric film is formed on a precious metal electrode. In this case, while a low frequency-band power source is used as a power source for applying a bias (i.e. a bias supply) to the stage, optimal frequencies for etching differ between the piezoelectric film and the precious metal. Therefore, the etch rate declines, and there is low selectivity with respect to an underlying film (the underlying film is removed due to over-etching).

In consideration of these, techniques for switching frequencies of a bias power source depending on a member to be etched are taught in Japanese Patent Application Publication No. 7-226393 and Japanese Patent Application Publication No. 2006-294848.

An apparatus described in Japanese Patent Application Publication No. 7-226393 uses a method of switching bias frequencies in order to switch between a radical mode and an ion mode. Specifically, a bias frequency of 13.56 MHz is used during a radical mode and a bias frequency of 800 kHz is used during an ion mode. Generally, a variable-frequency high-frequency power source is set to a frequency range of 200 kHz to 2 MHz and does not accommodate 13 MHz. Therefore, with the technique described in Japanese Patent Application Publication No. 7-226393, two power sources for 13.56 MHz and 800 kHz and the like are required. In addition, matching boxes are also required for respective frequencies.

Furthermore, since a method described in Japanese Patent Application Publication No. 2006-294848 similarly uses a low-frequency power source when etching precious metals and uses a high-frequency power source when etching a ferroelectric, then two power sources and two matching boxes are required.

As described above, switching frequencies of a bias power source requires two high-frequency power sources for applying a bias as well as two matching boxes, and results in an increase in cost of the apparatus.

### SUMMARY OF THE INVENTION

The present invention has been contrived in view of such circumstances, and an object of the present invention is to provide a dry etching apparatus and a method of dry etching which enable etching to be carried out at an optimal frequency for each member to be etched, using a single power source and a single matching box.

In order to attain an object described above, one aspect of the present invention is directed to a dry etching apparatus comprising: a vacuum chamber which includes therein a stage on which a member to be etched is mounted; a process gas supply device which supplies a process gas into the vacuum chamber; a plasma generating device which includes an electrode for generating a plasma in the vacuum chamber; a plasma generating power source which supplies high-frequency power for plasma generation to the electrode of the plasma generating device; a bias power source which is a single bias power source for controlling a self-bias potential of the stage and from which output frequency is variable; a matching box which is a single matching box connected electrically between the stage and the bias power source and which matches impedances between a load of the bias power source and the bias power source; a frequency setting device which sets an output frequency of the bias power source; and a control device which controls an impedance of the matching box according to the set output frequency of the bias power source.

According to this aspect of the invention, a single bias power source whose output frequency is variable, a single matching box which matches impedances between a load of the bias power source and the bias power source, and a control device which controls an impedance of the matching box according to an output frequency of the bias power source are provided, and therefore, it is possible to set an optimal bias frequency for etching a member being etched and to appropriately match impedances with respect to the set bias frequency. Consequently, dry etching can be carried out by switching frequencies using a single bias power source and a single matching box.

Desirably, the control device adjusts an inductance of a coil and/or a capacitance of a capacitor in the matching box to control the impedance of the matching box.

According to this aspect of the invention, it is possible to appropriately control an impedance of the matching box.

Desirably, the output frequency of the bias power source is not lower than 200 kHz and not higher than 2 MHz.

According to this aspect of the invention, it is possible to vary frequencies with a single bias power source and match impedances with a single matching box and, further, obtain sufficient etching performance.

Desirably, the dry etching apparatus further comprises a selecting device which selects a self-bias frequency suitable for etching of the member to be etched, wherein the frequency setting device sets the output frequency of the bias power source to the selected frequency.

According to this aspect of the invention, it is possible to carry out etching at a self-bias frequency suitable for etching a member being etched.

Desirably, the selecting device selects a first frequency suitable for etching the member to be etched during main etching, and selects, for over-etching, a second frequency having a high selectivity between the member to be etched and an underlying member with respect to the member to be etched.

According to this aspect of the invention, it is possible to respectively carry out etching at appropriate bias frequencies during main etching and over-etching.

Desirably, the dry etching apparatus further comprises: a measuring device which measures an emission intensity of the generated plasma; and a distinguishing device which distinguishes the main etching from the over-etching based on a measurement result of the measuring device, wherein the selecting device selects the self-bias frequency according to a distinguishing result of the distinguishing device.

According to this aspect of the invention, it is possible to appropriately distinguish between main etching and over-etching.

Desirably, the measuring device measures the emission intensity of the plasma by emission spectroscopy.

According to this aspect of the invention, it is possible to appropriately distinguish between main etching and over-etching.

Desirably, the distinguishing device distinguishes main etching from over-etching according to a point in time when the emission intensity measured by the measuring device decreases by a predetermined value from the emission intensity of the plasma during main etching.

According to this aspect of the invention, it is possible to appropriately distinguish between main etching and over-etching.

Desirably, the first frequency is not higher than 1 MHz and the second frequency is a frequency not less than 1.5 times the first frequency.

According to this aspect of the invention, it is possible to carry out etching in an appropriate fashion.

In order to attain an object described above, another aspect of the present invention is directed to a method of dry etching comprising the steps of: supplying a process gas into a vacuum chamber which includes therein a stage on which a member to be etched is mounted; supplying high-frequency power for plasma generation to an electrode of a plasma generating device to generate a plasma in the vacuum chamber; setting an output frequency of a single bias power source for controlling a self-bias potential of the stage to a desired value; and matching impedances between a load of the bias power source and the bias power source according to the set output frequency of the bias power source, using a single matching box which is electrically connected between the stage and the bias power source.

According to this aspect of the invention, an output frequency of a single bias power source for controlling a self-bias potential of a stage is set to an arbitrary value and, according to the set output frequency of the bias power source, impedances of a load of the bias power source and the bias power source are matched using a single matching box electrically connected between the stage and the bias power source. Therefore, it is possible to set an optimal bias frequency for etching a member being etched and achieve appropriate impedance matching with respect to the set bias frequency. Consequently, dry etching can be carried out by switching frequencies with a single bias power source and a single matching box.

Desirably, the member to be etched is a piezoelectric film.

According to this aspect of the invention, a piezoelectric film can be used as a member to be etched.

Desirably, the piezoelectric film is a lead zirconate titanate (PZT)

According to this aspect of the invention, it is possible to use a PZT film as the piezoelectric film described above.

According to the present invention, it is possible to carry out etching at a frequency which is optimal for each material (member) for etching using a single power source and a single matching box.

### BRIEF DESCRIPTION OF THE DRAWINGS

A preferred embodiment of this invention as well as other objects and benefits thereof, will be explained in the following with reference to the accompanying drawings, in which like reference characters designate the same or similar parts throughout the figures and wherein:

FIG. 1 is a cross-sectional view showing a general composition of a dry etching apparatus;

FIGS. 2A and 2B are diagrams showing a circuit configuration of a matching box;

FIGS. 3A to 3J are illustrative diagrams showing steps for manufacturing a piezoelectric element;

FIG. 4 is a diagram showing output of a plasma monitor over time when etching a PZT film;

FIG. 5 is a graph showing etch rates and selectivity of PZT and Pt;

FIGS. 6A to 6C are illustrative diagrams showing steps for etching;

FIG. 7 is a graph showing etch rates and selectivity of Pt and SiO₂; and

FIG. 8 is a graph showing etch rates and selectivity of Pt and SiO₂.

### DETAILED DESCRIPTION OF THE PREFERRED EMBODIMENTS

### Overall Composition of Dry Etching Device

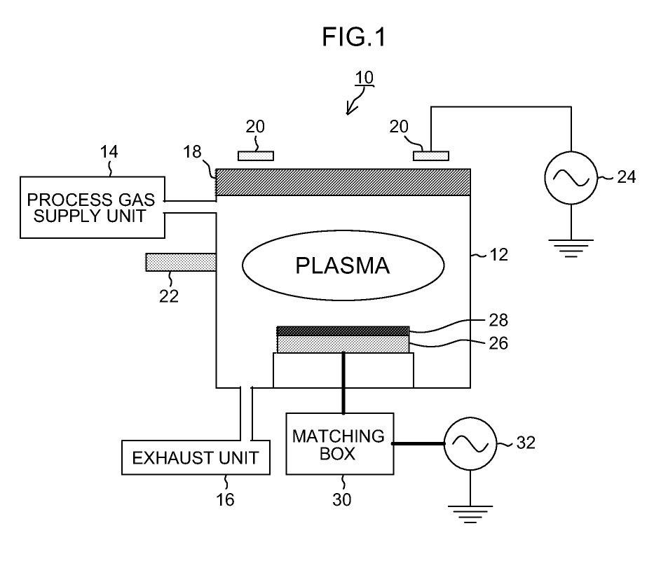

FIG. 1 is a cross-sectional view showing a general composition of a dry etching apparatus relating to one embodiment of the present invention. The dry etching apparatus 10 shown in FIG. 1 comprises a process gas supply unit 14 which supplies a process gas (etching gas) into a chamber 12 (vacuum chamber), an exhaust unit 16 which expels gas from the chamber 12, and a pressure adjustment unit (not illustrated) which adjusts the pressure inside the chamber 12. By supplying the process gas from the process gas supply unit 14 into the chamber 12 while expelling the gas via the gas exhaust unit 16, the pressure inside the chamber 12 can be adjusted.

A dielectric window 18 is installed in a sealed fashion on the upper surface of the chamber 12, and furthermore, a loop coil-shaped antenna 20 is provided on the upper side (the atmosphere side) of the dielectric window 18. A high-frequency power source (RF power source) 24 for generating a plasma is connected to the antenna 20 via a matching box (not illustrated). The frequency of the high-frequency power source 24 for plasma generation is from 13.56 MHz to 60 MHz; for example, a frequency of 13.56 MHz can be used. Furthermore, the high-frequency power source 24 for plasma generation may also be driven in a pulsed fashion.

A substrate cooling mechanism (not illustrated) equipped with an electrostatic chuck or a clamp is provided on the stage 26 inside the chamber 12, and a substrate 28 which forms a member being etched is mounted on the stage 26. A low-frequency power source 32 for applying a bias is connected to the stage 26 via a matching box 30.

The matching box 30 is configured to match an impedance of the low-frequency power source 32 for applying a bias and an impedance of connected loads of the low-frequency power source 32 for applying a bias including the matching box 30 in order to supply maximum power from the low-frequency power source 32 for applying a bias to the stage 26.

A power source whose frequency is variable within a range of 200 kHz to 2 MHz is used as the low-frequency power source 32 for applying a bias. In the same manner as the high-frequency power source 24 for generating a plasma, the low-frequency power source 32 for applying a bias may be driven in a pulsed fashion. In addition, when the high-frequency power source 24 for generating a plasma and the low-frequency power source 32 for applying a bias are driven in a pulsed fashion, it is desirable to provide a device for synchronizing pulse periods of the respective power sources.

The dry etching apparatus 10 configured as described above applies power to the antenna 20 from the high-frequency power source 24 for generating a plasma while supplying and expelling the process gas, in such a manner that an electromagnetic wave is radiated into the chamber 12 from the antenna 20 via the dielectric window 18, and a high-density plasma is caused to be generated inside the chamber 12.

At the same time, when a self-bias voltage is applied from the low-frequency power source 32 for applying a bias to the stage 26, ions are extracted from the generated plasma and inputted to (incident onto) the substrate 28, and the substrate 28 on the stage 26 is etched.

During this, the plasma monitor 22 detects an intensity change of an emission spectrum line inside the chamber 12 by emission spectroscopy.

Moreover, although the dry etching apparatus 10 according to the present embodiment is an apparatus employing an Inductive Coupling Plasma (ICP) system as shown in FIG. 1, implementation of embodiments of the present invention is not limited to the present example. For example, it is possible to apply embodiments of the present invention to an apparatus using a source of plasma such as a helicon wave, ECR (Electron Cyclotron Resonance), and SWP (Surface Wave Plasma), or a parallel plate type of apparatus.

Halogen gas may be used as the process gas (etching gas). For example, it is possible to use Cl₂ (chlorine), BCl₃ (boron trichloride), HBr (hydrogen bromide), SF₆ (sulfur hexafluoride), CF₄ (carbon tetrafluoride), CHF₃ (trifluoromethane), C₂F₆ (hexafluoroethane), C₃F₈ (octafluoropropane), C₄F₆ (hexafluorobutadiene), C₄F₈ (octafluorocyclobutane), and C₅F₈ (octafluorocyclopentene), or mixed gases of the same. It is also possible to use an inert gas such as Ar (argon) or a mixed gas of O₂ (oxygen), N₂ (nitrogen), or the like.

Moreover, the process gas desirably has a flow rate equal to or higher than 1 sccm and equal to or lower than 1000 sccm and a degree of vacuum (pressure) approximately equal to or higher than 0.01 Pa and equal to or lower than 10 Pa.

### Composition of Matching Box

Next, a composition of the matching box 30 will be described.

As described above, in the dry etching apparatus 10, a frequency (bias frequency) of the low-frequency power source 32 for applying a bias is variable. In association thereto, the matching box 30 is capable of matching impedances according to a set bias frequency by varying capacities of a coil and a capacitor inside the matching box 30.

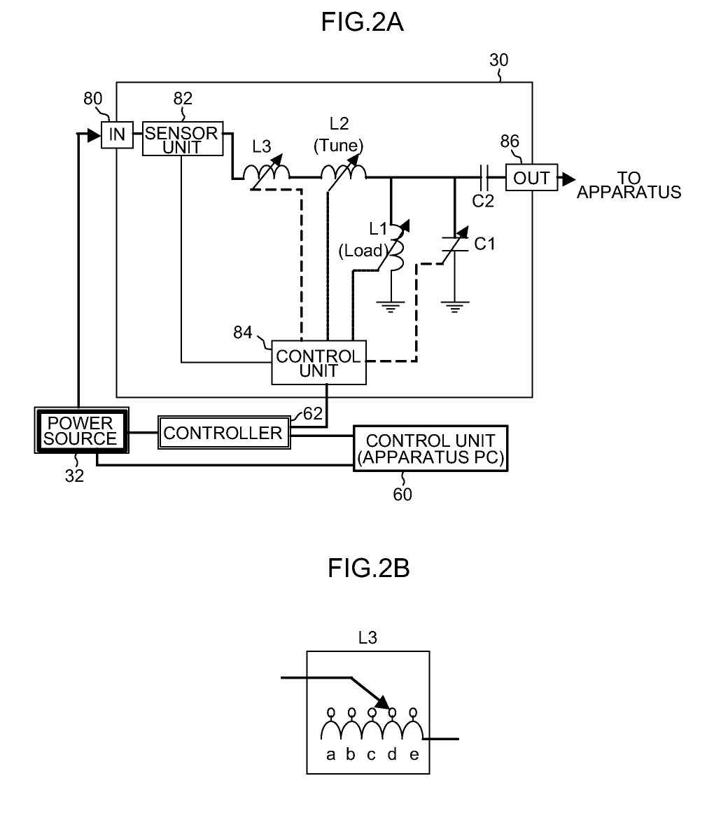

FIG. 2A is a diagram showing a circuit composition of the matching box 30. As shown in FIG. 2A, the matching box 30 includes an input unit 80, a sensor unit 82, a control unit 84, and an output unit 86, as well as a load coil L1, a tuning coil L2, an adjustment coil L3, an adjustment capacitor C1, and a coupling capacitor C2.

As shown in FIG. 2A, an output of the low-frequency power source 32 for applying a bias is inputted to the input unit 80 of the matching box 30. Moreover, when a cover of a chassis of the matching box 30 is opened, an interlock signal is transmitted from a controller 62 to the low-frequency power source 32 for applying a bias to suspend output from the low-frequency power source 32 for applying a bias.

A bias frequency can be varied by outputting a bias frequency setting signal from a control unit 60 of the dry etching apparatus 10 to the low-frequency power source 32 for applying a bias and the controller 62.

Upon receiving the bias frequency setting signal, the low-frequency power source 32 for applying a bias switches an output frequency to a frequency corresponding to the setting signal.

In addition, the controller 62 outputs the received bias frequency setting signal to the control unit 84 of the matching box 30. The control unit 84 adjusts an inductance of the adjustment coil L3 and a capacitance of the adjustment capacitor C1 inside the matching box 30 to obtain an optimal impedance with respect to the set bias frequency.

A tapped coil (with a tap) such as that shown in FIG. 2B is used as the adjustment coil L3. With the tapped coil, it is possible to vary the number of active turns of the coil by switching a tap position among a to e. Accordingly, it is possible to vary an inductance of the adjustment coil L3 to a predetermined value equal to or higher than 5 μH and equal to or lower than 200 μH. The control unit 84 switches a tap position of the adjustment coil L3 using a tap switching device (not illustrated) to switch the inductance of the adjustment coil L3.

Moreover, it is also possible to use a variable inductance coil as the adjustment coil L3.

In addition, a variable capacitor is used as the adjustment capacitor C1, whereby the control unit 84 switches the capacitance of the adjustment capacitor C1 using a capacitance switching device (not illustrated).

For example, if the bias frequency is 500 kHz, then the control unit 84 sets the adjustment coil L3 to 30 μH and the adjustment capacitor to 2100 pF, and if the bias frequency is 999 kHz, then the control unit 84 sets the adjustment coil L3 to 15 μH and the adjustment capacitor to 1000 pF. The inductance of the adjustment coil L3 and the capacitance of the adjustment capacitor C1 with respect to the set bias frequency may be stored in advance in the control unit 60 or the control unit 84.

Moreover, fine adjustment of the impedance of the matching box 30 is carried out by varying inductances of the load coil L1 and the tuning coil L2. The sensor unit 82 determines values of a voltage and a current inputted from the low-frequency power source 32 for applying a bias to the input unit 80, and outputs the same to the control unit 84. The control unit 84 calculates a load impedance of the low-frequency power source 32 for applying a bias based on the values inputted from the sensor unit 82, varies inductances of the load coil L1 and the tuning coil L2 based on the calculated load impedance, and finely adjusts a matched impedance according to the set frequency. Accordingly, it is possible to carry out impedance matching in an appropriate fashion.

Power whose impedance is matched in this fashion is outputted from the output unit 86 via the coupling capacitor C2 and applied to the stage 26 inside the chamber 12 of the dry etching apparatus 10.

### First Embodiment

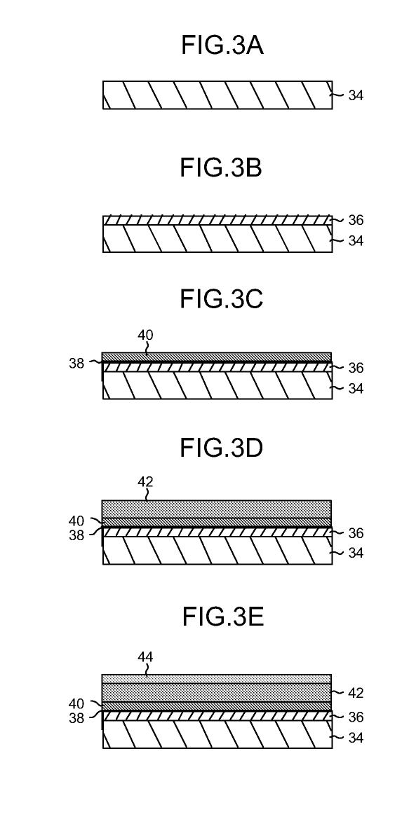

FIGS. 3A to 3J are illustrative diagrams showing steps for manufacturing a piezoelectric element. Firstly, an insulating film 36 is formed on a silicon substrate (Si substrate) 34 shown in FIG. 3A (FIG. 3B). Thereupon, an adhesive layer 38 is formed on the insulating film 36 and a lower electrode film (precious metal film) 40 is formed on top of the adhesive layer 38 (FIG. 3C). Next, a piezoelectric film (ferroelectric film) 42 is formed on the lower electrode film 40 (FIG. 3D), and an upper electrode film (precious metal film) 44 is formed on the piezoelectric film 42 (FIG. 3E). For example, the insulating film 36 is an oxide film (SiO₂ film), which can be formed by sputtering, CVD (Chemical Vapor Deposition), or thermal oxidation. Furthermore, the adhesive layer 38 is a titanium layer (Ti layer), which can be formed by sputtering. Moreover, the lower electrode film 40 and the upper electrode film 44 are films of a precious metal, such as platinum (Pt), iridium (Ir), ruthenium (Ru), or oxides of same, which can be formed by sputtering, CVD, or the like. Furthermore, the piezoelectric film 42 is a PZT film (lead zirconate titanate), which can be formed by sputtering or CVD.

Next, a resist 46 is formed (applied) onto the upper electrode film 44, and respective processes of pre-baking (soft baking), exposure, development and post-baking are carried out in sequence, and the resist 46 is patterned into a prescribed shape (FIG. 3F). Thereupon, the upper electrode film 44 is patterned by dry etching, using the patterned resist 46 as a mask (FIG. 3G).

Next, a mask layer 48 is formed over the piezoelectric film 42 (FIG. 3H). It is possible to use a resist or an oxide film as the mask layer 48. Furthermore, it is also possible to use a hard mask made of metal, or the like. Of these options, a desirable mode is one which uses a resist as the mask layer 48. In this case, a resist is formed on the piezoelectric film 42 by spin coating, or the like, and it is desirable that respective processes of pre-baking (soft baking), exposure, development and post-baking should be carried out in sequence, and the resist should be patterned into a prescribed shape. In this case, instead of post-baking, it is also possible to carry out UV (ultraviolet) curing.

If a hard mask is used as the mask layer 48, then a photolithography step and an etching step for depositing and patterning a hard mask are required. On the other hand, if a resist mask is used, then the patterning of the hard mask becomes unnecessary and the number of steps required to manufacture the mask are reduced and the costs can be lowered. Consequently, from the viewpoint of reducing costs, a desirable mode is one which uses a resist.

Next, dry etching of the piezoelectric film 42 is carried out (FIG. 3I). More specifically, a substrate 50 (member to be etched) on which the piezoelectric film 42 has been formed is placed on the stage 26 inside the chamber 12 of the dry etching apparatus 10 shown in FIG. 1. Thereupon, the interior of the chamber 12 is set to a vacuum state, then gas discharge is executed via the exhaust unit 16 while a process gas is supplied from the process gas supply unit 14, whereby the internal pressure of the chamber 12 is regulated to a prescribed pressure.

In the present embodiment, a mixed gas of Cl₂ and C₄F₈ respectively having flow rates of Cl₂=10 sccm and C₄F₈=40 sccm is used as the process gas. In addition, the pressure inside the chamber 12 is set to 0.7 Pa.

Thereupon, a high-frequency wave of 13.56 MHz is applied to the antenna 20 at a power of 475 W by the high-frequency power source 24 for generating a plasma, and an electromagnetic wave is radiated into the chamber 12 from the antenna 20 via the dielectric window 18, thereby generating a high-density plasma inside the chamber 12. During this, a low frequency of 500 kHz is applied at a power of 100 W to the stage 26 by the low-frequency power source 32 for applying a bias. By this means, the piezoelectric film 42 is etched in the portion which is not covered with the mask layer 48, and the piezoelectric film 42 is thereby patterned into a shape corresponding to the mask layer 48.

In this case, while a frequency of the low-frequency power source 32 for applying a bias is set to 500 kHz during main etching of the piezoelectric film 42 (until the lower electrode film 40 which is an underlying film is reached), the frequency is then switched to 999 kHz during over-etching (after reaching the lower electrode film 40 which is an underlying film).

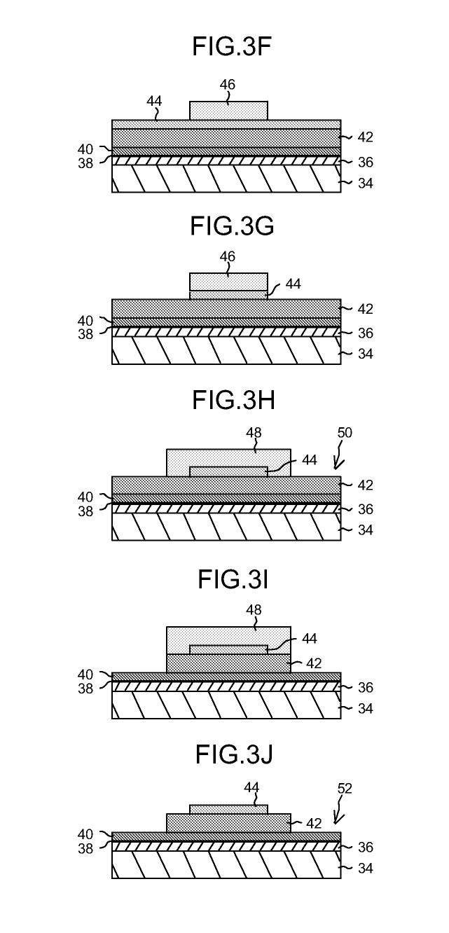

FIG. 4 is a diagram which shows output of the plasma monitor 22 over time when a PZT film is etched and which represents a result of monitoring 406 nm which is an emission wavelength of Ti.

As shown in FIG. 4, an emission intensity of Ti increases as etching starts, and subsequently stabilizes and indicates a constant intensity. In addition, the intensity drops as time further elapses. A state where the intensity is stable is main etching and a state where the intensity drops (is decreased) is over-etching. Therefore, a point in time where the lower electrode film 40 which is an underlying film is reached (just etching) should be determined from the output of the plasma monitor 22 in order to switch frequencies of the low-frequency power source 32 for applying a bias. For example, if emission intensity continues to decrease by 5 to 20% from a steady value, then a point in time of the start of the decrease is determined as a just etching. Moreover, a determination of the just etching may be carried out as appropriate.

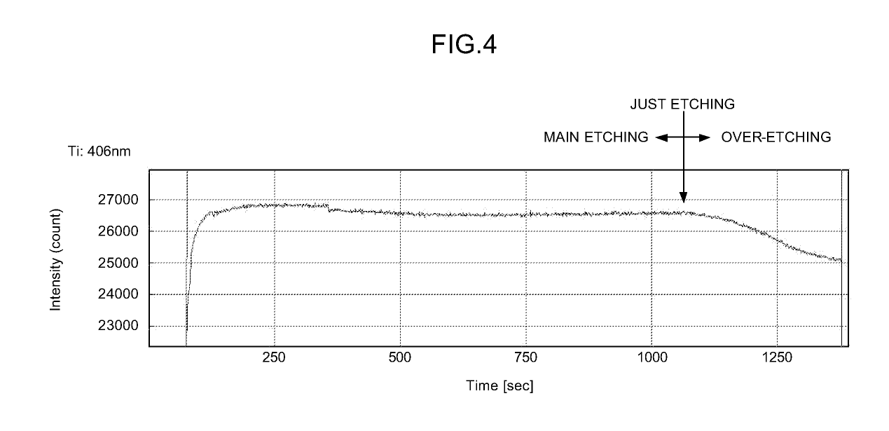

Dependency of etch rates of PZT and Pt to bias frequency will now be described. FIG. 5 is a graph showing an etch rate of PZT and an etch rate of Pt, as well as a selectivity (PZT/Pt) calculated from the etch rates, when an output of the low-frequency power source 32 for applying a bias is set to 100 W and frequencies of the same are set to 500 kHz, 750 kHz, and 999 kHz.

As shown in FIG. 5, when the bias frequency is 500 kHz, the etch rate of PZT is high but the selectivity of Pt is low. In addition, when the bias frequency is 999 kHz, the etch rate of PZT is low but the selectivity of Pt is high.

The above results show that by carrying out main etching at 500 kHz, the etch rate can be increased and productivity can be improved, and by carrying out over-etching at 999 kHz, deletion of an electrode of the underlying layer can be prevented and device reliability can be improved.

In other words, during the etching of the piezoelectric film 42, it is desirable that the etching should be started by setting the bias frequency to 500 kHz, and once a just etching is detected from the output of the plasma monitor 22, the bias frequency should be switched to 999 kHz.

While the bias frequency during over-etching is set to 999 kHz in this case, the bias frequency during over-etching may be set to 750 kHz instead. In other words, as shown in FIG. 5, since the selectivity of Pt is high even when the bias frequency is set to 750 kHz, it is possible to adopt 750 kHz as the bias frequency during over-etching. In this case, the bias frequency during over-etching of 750 kHz is 1.5 times the bias frequency during main etching of 500 kHz.

As described above, it is apparent that optimal etching is possible by setting the bias frequency for main etching to 1 MHz or lower and setting the bias frequency for over-etching to a frequency which is equal to or higher than 1.5 times the bias frequency for main etching.

Returning now to the description on FIG. 3A to 3J, by finally removing the mask layer 48, it is possible to form a piezoelectric element 52 made up of the lower electrode film 40, the piezoelectric film 42, and the upper electrode film 44 on the silicon substrate 34 (FIG. 3J).

In the present embodiment, while an optimal bias frequency is selected from a range of 500 kHz to 999 kHz by comparing an etch rate and selectivity, it is needless to say a range from which a bias frequency is selectable is not limited to this range. Here, a frequency of the low-frequency power source 32 for applying a bias can be varied within a range of 200 kHz to 2 MHz, and the matching box 30 also enables impedances to be matched within the same frequency range. Therefore, depending on members for etching, it is possible to select an optimal bias frequency from a range of 200 kHz to 2 MHz by comparing an etch rate and selectivity.

### Second Embodiment

Consecutive etching of a laminated film is carried out in a second embodiment. In this case, an example of consecutive etching of a piezoelectric film layer formed sandwiched between electrodes on a silicon substrate will be described.

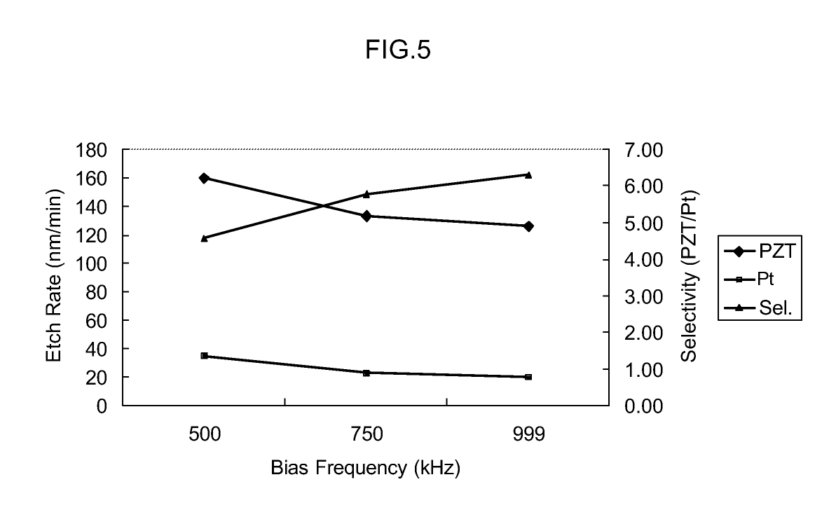

FIGS. 6A to 6C are illustrative diagrams showing steps for etching according to the present embodiment, wherein parts shared with FIGS. 3A to 3J are denoted using similar or the same reference numerals.

As shown in FIG. 6A, in a laminated film to be etched in the present embodiment, an insulating film 36 is formed on a silicon substrate 34, an adhesive layer 38 is formed on the insulating film 36, a lower electrode film 40 is formed on the adhesive layer 38, a piezoelectric film 42 is formed on the lower electrode film 40, and an upper electrode film 44 is formed on the piezoelectric film 42. As in the case of the first embodiment, the piezoelectric film 42 is a PZT film, and Pt is used for the upper electrode film 44.

Furthermore, an oxide film 90 which is a hard mask is formed on the upper electrode film 44. Moreover, a resist 92 for patterning the oxide film 90 is patterned on the oxide film 90. The resist 92 can be patterned in the same fashion as the resist 46 described earlier.

In the present embodiment, consecutive etching of a piezoelectric film layer formed as described above is carried out.

First, the oxide film 90 is etched using the resist 92. As etching conditions, for example, it is possible to use a fluoride-containing gas or an inert gas as a process gas and to set the pressure to around 0.2 to 5 Pa. In this case, C₄F₈ and Ar are used as the process gas, respective gas flow rates of C₄F₈=5 sccm and Ar=45 sccm are set, pressure is set to 0.6 Pa, an output of the high-frequency power source 24 for generating a plasma is set to 500 W, and an output of the low-frequency power source for applying a bias is set to 100 W.

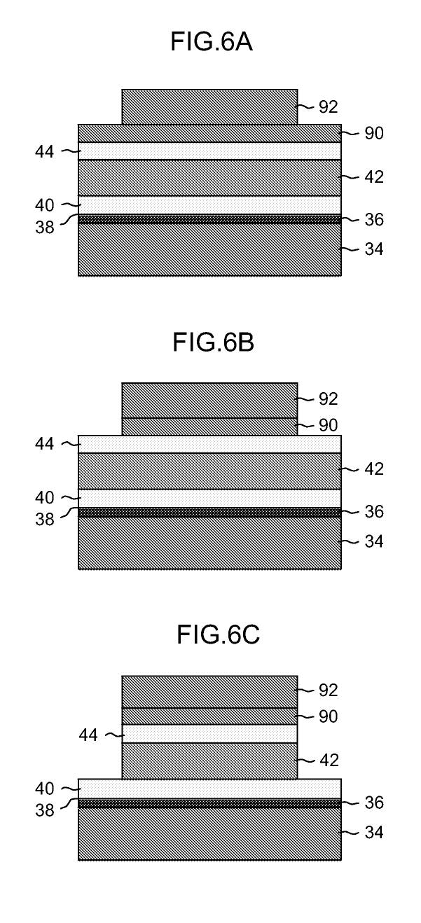

Dependency of etch rates of the oxide film 90 and the upper electrode film 44 to bias frequency under the above etching conditions will now be described. FIG. 7 is a graph showing an etch rate of SiO₂ and an etch rate of Pt, as well as a selectivity (SiO₂/Pt) calculated from the etch rates, when an output of the low-frequency power source 32 for applying a bias is set to 100 W and frequencies of the same are set to 500 kHz, 750 kHz, and 999 kHz.

As shown in FIG. 7, selectivity is highest when the bias frequency is 999 kHz. Therefore, by setting the bias frequency to 999 kHz, it is possible to reduce removal of the upper electrode film 44 which is an underlying film in order to etch the oxide film 90 in an appropriate fashion (FIG. 6B).

Next, using the oxide film 90 as a mask, the upper electrode film 44 is processed by dry etching. As etching conditions, for example, it is possible to use a chlorine-containing gas or an inert gas as a process gas and to set the pressure to around 0.2 to 5 Pa. In this case, Cl₂ and Ar are used as the process gas, respective gas flow rates of Cl₂=10 sccm and Ar=40 sccm are set, the pressure is set to 0.2 Pa, an output of the high-frequency power source 24 for generating a plasma is set to 500 W, and an output of the low-frequency power source for applying a bias is set to 75 W.

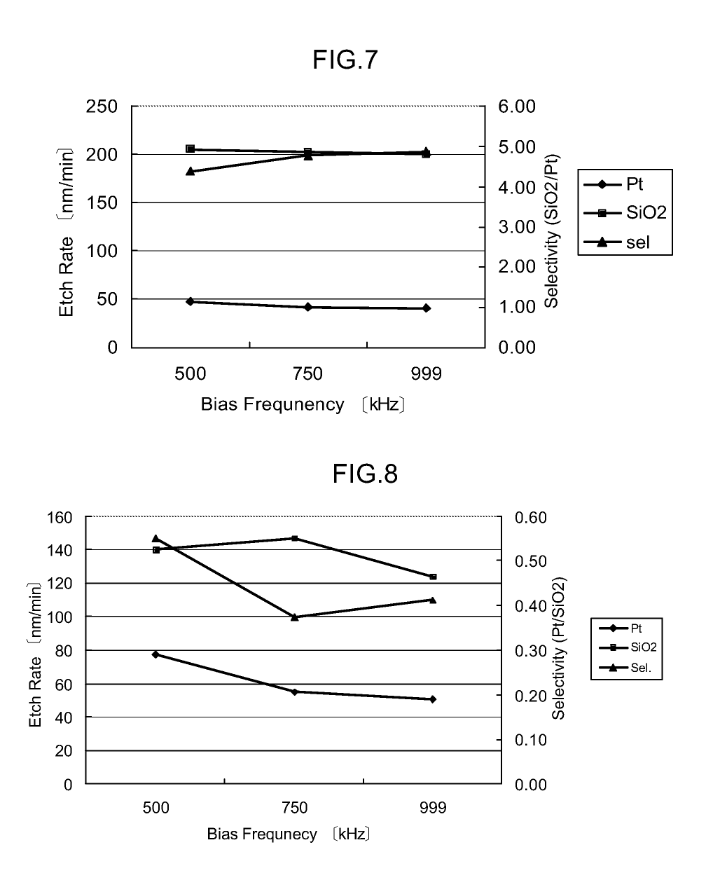

Dependency of etch rates of the oxide film 90 which becomes a mask and the upper electrode film 44 which is a member to be etched to bias frequency under the above etching conditions will now be described. FIG. 8 is a graph showing an etch rate of SiO₂ and an etch rate of Pt, as well as a selectivity (Pt/SiO₂) calculated from the etch rates, when an output of the low-frequency power source 32 for applying a bias is set to 100 W and frequencies of the same are set to 500 kHz, 750 kHz, and 999 kHz.

As shown in FIG. 8, mask selectivity and the etch rate of Pt are both high when the bias frequency is 500 kHz. Therefore by setting the bias frequency to 500 kHz, it is possible to etch the upper electrode film 44 in an appropriate fashion (FIG. 6C).

Next, the piezoelectric film 42 is etched. The etching conditions and the like for the piezoelectric film 42 is the same as those described in the first embodiment using FIG. 3I. The bias frequency of main etching is set to 500 kHz, and after detecting a just etching by a plasma monitor 22, the bias frequency is switched to 999 kHz to carry out over-etching.

As described above, the bias frequency is set to 999 kHz when etching the oxide film 90 which is a hard mask and then to 500 kHz when etching the upper electrode film 44. Furthermore, the bias frequency is changed from 500 kHz to 999 kHz when etching the piezoelectric film 42. As described, by adopting a variable bias frequency during consecutive etching of a laminated film and by using an optical frequency, it is possible to achieve high-accuracy and high-speed etch processing with a high etch rate and high selectivity with respect to an underlying layer.

Moreover, as for timings for switching the bias frequencies, an etching time for each film may be determined in advance or the timings for switching may be determined from an output of the plasma monitor 22 as is the case in the first embodiment.

It should be understood that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A dry etching apparatus comprising:
a vacuum chamber which includes therein a stage on which a member to be etched is mounted;
a process gas supply device which supplies a process gas into the vacuum chamber;
a plasma generating device which includes an electrode for generating a plasma in the vacuum chamber;
a plasma generating power source which supplies high-frequency power for plasma generation to the electrode of the plasma generating device;
a bias power source which is a single bias power source for controlling a self-bias potential of the stage and from which output frequency is variable;
a matching box which is a single matching box connected electrically between the stage and the bias power source and which matches impedances between a load of the bias power source and the bias power source;
a frequency setting device which sets an output frequency of the bias power source; and
a control device which controls an impedance of the matching box according to the set output frequency of the bias power source.

2. The dry etching apparatus as defined in claim 1, wherein the control device adjusts an inductance of a coil and/or a capacitance of a capacitor in the matching box to control the impedance of the matching box.

3. The dry etching apparatus as defined in claim 1, wherein the output frequency of the bias power source is not lower than 200 kHz and not higher than 2 MHz.

4. The dry etching apparatus as defined in claim 1, further comprising a selecting device which selects a self-bias frequency suitable for etching of the member to be etched,
wherein the frequency setting device sets the output frequency of the bias power source to the selected frequency.

5. The dry etching apparatus as defined in claim 4, wherein the selecting device selects a first frequency suitable for etching the member to be etched during main etching, and selects, for over-etching, a second frequency having a high selectivity between the member to be etched and an underlying member with respect to the member to be etched.

6. The dry etching apparatus as defined in claim 5, further comprising:
a measuring device which measures an emission intensity of the generated plasma; and
a distinguishing device which distinguishes the main etching from the over-etching based on a measurement result of the measuring device,
wherein the selecting device selects the self-bias frequency according to a distinguishing result of the distinguishing device.

7. The dry etching apparatus as defined in claim 6, wherein the measuring device measures the emission intensity of the plasma by emission spectroscopy.

8. The dry etching apparatus as defined in claim 6, wherein the distinguishing device distinguishes main etching from over-etching according to a point in time when the emission intensity measured by the measuring device decreases by a predetermined value from the emission intensity of the plasma during main etching.

9. The dry etching apparatus as defined in claim 5, wherein the first frequency is not higher than 1 MHz and the second frequency is a frequency not less than 1.5 times the first frequency.

10. A method of dry etching comprising the steps of:
supplying a process gas into a vacuum chamber which includes therein a stage on which a member to be etched is mounted;
supplying high-frequency power for plasma generation to an electrode of a plasma generating device to generate a plasma in the vacuum chamber;
setting an output frequency of a single bias power source for controlling a self-bias potential of the stage to a desired value; and
matching impedances between a load of the bias power source and the bias power source according to the set output frequency of the bias power source, using a single matching box which is electrically connected between the stage and the bias power source.

11. The method of dry etching as defined in claim 10, wherein the member to be etched is a piezoelectric film.

12. The method of dry etching as defined in claim 11, wherein the piezoelectric film is a lead zirconate titanate (PZT) film.
